(19) United States
(12) Patent Application Publication
(10) Pub. No.: US 2007/0176276 A1
(43) Pub. Date: Aug. 2, 2007

(54) Semiconductor die assembly

(76) Inventors: Debbie Forray, San Diego, CA (US); Mario Gattuso, San Diego, CA (US)

Correspondence Address: Kevin Forrestal Designer Molecules Inc., 10080 Willow Creek Road, San Diego, CA, 92131, US

(21) Appl. No.: 11/344,494

(22) Filed: Feb. 1, 2006

(51) Int. Cl. H01L 23/02

(52) U.S. Cl. 257/686; 257/E23.085

(57) ABSTRACT

The invention is based on the discovery that certain well-defined b-stageable adhesives are useful in stacked die assemblies. In particular, the invention provides assemblies wherein the b-stageable adhesive encapsulates a portion of the wiring members contained within the bondline gap between the stacked die. In other words, the b-stageable adhesive has the ability to flow through (i.e., encapsulate) the wires as the adhesive fills the bondline gap, thereby preventing any mold compound from covering the wires.

### RELATED APPLICATION DATA

This application claims the benefit of priority of U.S. Provisional Application Ser. No. 60/647,520 filed Jan. 27, 2005, the entire disclosure of which is incorporated herein by reference.

### FIELD OF THE INVENTION

The invention relates generally to semiconductor assemblies containing more than one die, and particularly to stacked die assemblies and methods for producing such assemblies.

### BACKGROUND OF THE INVENTION

Adhesive compositions, particularly conductive adhesives, are used for a variety of purposes in the fabrication and assembly of semiconductor packages and microelectronic devices. The more prominent uses include bonding of electronic elements such as integrated circuit chips to lead frames or other substrates, and bonding of circuit packages or assemblies to printed wire boards. Adhesives useful for electronic packaging applications typically exhibit properties such as good mechanical strength, curing properties that do not affect the component or the carrier, and rheological properties compatible with application to microelectronic and semiconductor components.

Recently, there has been an increased interest in b-stageable adhesives. A b-stageable material is actually a thermosetting material that has a first solid phase followed by a rubbery stage at elevated temperature, followed by yet another solid phase at an even higher temperature. The transition from the rubbery stage to the second solid phase is thermosetting. However, prior to that, the material behaves similarly to a thermoplastic material. Thus, such a material would permit low lamination temperatures while providing high thermal stability. In addition, b-stageable adhesives eliminate many of the storage, handling, dispensing, and processing issues that exist when dispensing an adhesive in a flowable form.

Due to the ever increasing pressure to reduce the size of semiconductor packages, there has been a recent interest in thinner die with increasingly thinner bondlines, and the use of these thin die in stacked packages (i.e., at least one die stacked on top of another). These types of assemblies conserve circuit board real estate without sacrificing overall performance of a device containing such an assembly. It is recognized that there is a need for b-stageable adhesives in just such an assembly. The invention set forth herein addresses this need.

### SUMMARY OF THE INVENTION

The invention is based on the discovery that certain well-defined b-stageable adhesives are useful in stacked die assemblies. In particular, the invention provides assemblies wherein the b-stageable adhesive encapsulates a portion of the wiring members contained within the bondline gap between the stacked die. In other words, the b-stageable adhesive has the ability to flow through (i.e., encapsulate) the wires as the adhesive fills the bondline gap, thereby preventing any mold compound from covering the wires. This situation is quite advantageous since it is known that mold compound encapsulation of the wiring members creates a CTE (coefficient of thermal expansion) mismatch.

In one embodiment of the invention, there is provided a semiconductor die assembly including:
a) a substrate having wiring members extending from pads on the substrate for electrically connecting a die to the substrate,
b) a bottom die having a rear surface and a front surface, wherein the rear surface faces the substrate, and wherein the front surface of the bottom die has electrical pads for attaching a wiring member from the substrate, and wherein a first die-attach adhesive is disposed between the substrate and rear surface of the bottom die,
c) a first top die having a rear surface and a front surface, wherein the first top die is positioned above the bottom die so that the rear surface of the first top die is facing the front surface of the bottom die, thereby creating a first bondline gap between the bottom die and the top die, wherein a portion of twiring members extending from the electrical pads on the front surface of the bottom die are located within the first bondline gap, and
d) a second die-attach adhesive disposed between the bottom die and the top die, thereby filling the first bondline gap and creating a first bondline, and encapsulating the portion of the wiring members located within the first bondline.

### BRIEF DESCRIPTION OF THE FIGURES

FIG. 1 depicts a cross-section of a semiconductor die assembly according to the invention. In this Figure, the assembly is a stacked die assembly containing 4 die, with a b-stageable adhesive according to the invention disposed between each die.

FIG. 2 is a cross-section in greater detail showing the adhesive of the invention encapsulating the gold wire bonds within the bondline, thereby preventing mold compound from flowing into the bondline and damaging the wire bonds.

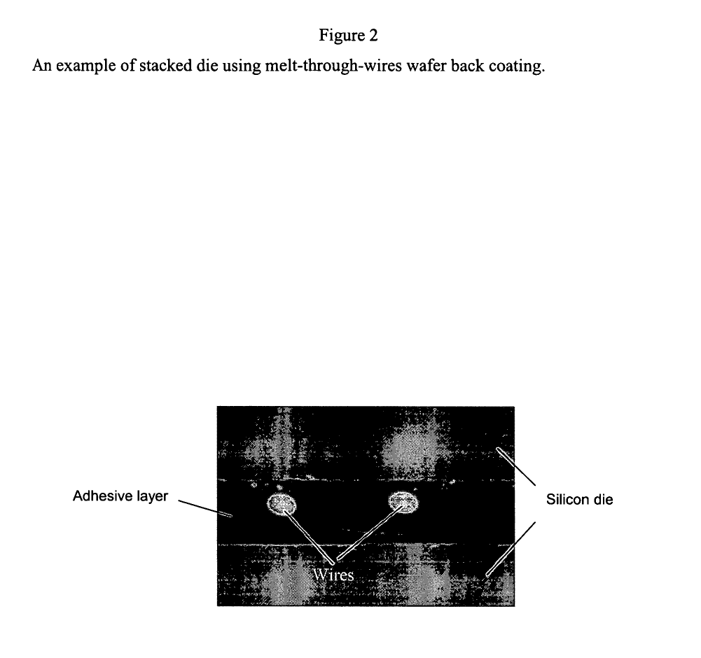

FIG. 3 depicts a stacked die package containing a dummy die. As shown in the Figure, the wire bonds are not encapsulated by the die attach adhesive, and therefore are susceptible to damage when the mold compound is applied to the package.

FIG. 4 depicts a stacked die package using spacer paste as die attach adhesive.

### DETAILED DESCRIPTION OF THE INVENTION

The invention is based on the discovery that certain well-defined b-stageable die attach adhesives are useful in stacked die assemblies. In particular, the invention provides assemblies wherein the b-stageable die attach adhesive encapsulates a portion of the wiring members contained within the bondline gap between the stacked die. In other words, the b-stageable adhesive has the ability to flow through (i.e., encapsulate) the wires as the adhesive fills the bondline gap, thereby preventing any mold compound from covering the wires.

As used herein, “b-stageable” means that the adhesive has a first solid phase followed by a rubbery stage at elevated temperature, followed by yet another solid phase at an even higher temperature. The transition from the rubbery stage to the second solid phase is thermosetting. However, prior to that, the material behaves similarly to a thermoplastic material. Thus, such an adhesive allows for low lamination temperatures while providing high thermal stability.

As used herein, “bondline” refers generally to the thickness of the adhesive layer between adherends.

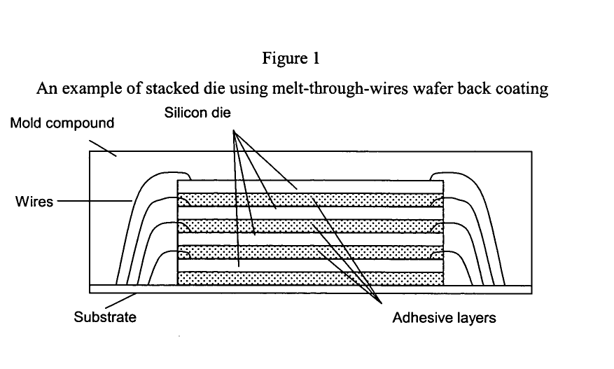

For example, FIG. 1 shows a cross-sectional view of an assembly containing 4 stacked die, with a well-defined b-stageable die attach adhesive described herein disposed between each of the die. In some embodiments, the bondline thickness is 1 to 10 mils. In other embodiments, the bondline thickness is 1 to 5 mils. In still other embodiments, the bondline thickness is 1 to 3 mils. This demonstrates that the b-stageable die attach adhesive described herein is useful for producing stacked die packages with very thin die and bondlines. In certain embodiments, the assembly includes at least 2 die. In other embodiments, the assembly includes at least 3 die. In other embodiments, the assembly includes at least 4 die.

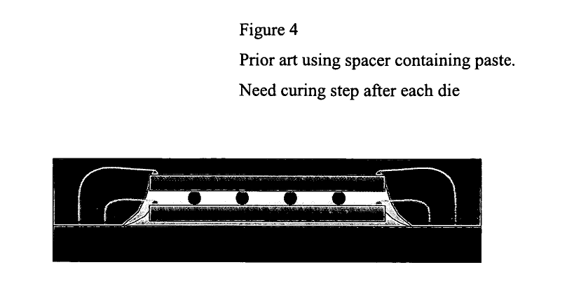

The invention described herein has particular advantages over other stacked die assemblies using spacer pastes or dummy die. With respect to spacer pastes (see FIG. 4), the invention described herein provides uniform bondline thickness and die attach coverage. In addition, in contrast to assemblies using spacer pastes, there is no die tilt or die shift, no overflowing to the die top (especially for thin die), and no fillet. Thus, the present invention is ideal for tight tolerance packages. Moreover, the present invention provides an additional manufacturing advantage since there is only one oven cure process prior to molding.

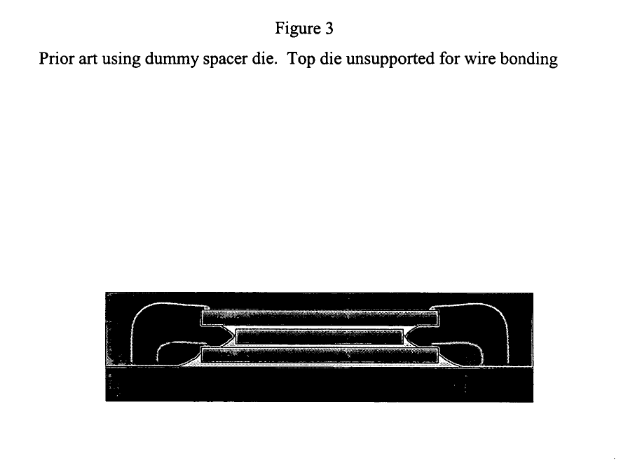

With respect to assemblies containing dummy die (see FIG. 3), the assemblies described herein have a significantly reduced bondline gap thus allowing stacking of more die or thinner package height. In addition, the back-grinding, dicing, die attach and curing processes and expensive wafer back laminating tape for the dummy die are eliminated. More importantly, the invention supports the top die all the way to the die edge which is essential for wire bonding of the top die.

The b-stageable adhesive can be dispensed onto a die or a substrate by a variety of methods well known to those skilled in the art. In some embodiments, the adhesive is cast from solution using techniques such as spin coating, spray coating, stencil printing, screen printing, and the like.

In some embodiments, there is at least one co-monomer typically present in the b-stageable adhesive composition from 10 wt % to about 90 wt % based on total weight of the b-stageable adhesive composition. Such comonomers include, for example, acrylates, methacrylates, maleimides, vinyl ethers, vinyl esters, styrenic compounds, allyl functional compounds, and the like.

The at least one curing initiator is typically present in the b-stageable adhesive composition from 0.1 wt % to about 5 wt % based on total weight of the b-stageable adhesive composition, and is typically a free-radical initiator. As used herein, the term “free radical initiator” refers to any chemical species which, upon exposure to sufficient energy (e.g., light, heat, or the like), decomposes into two parts which are uncharged, but which each possess at least one unpaired electron. Preferred free radical initiators contemplated for use in the practice of the present invention are compounds which decompose (i.e., have a half life in the range of about 10 hours) at temperatures in the range of about 70° C. up to 180° C. Exemplary free radical initiators contemplated for use in the practice of the present invention include peroxides (e.g., dicumyl peroxide, dibenzoyl peroxide, 2-butanone peroxide, tert-butyl perbenzoate, di-tert-butyl peroxide, 2,5-bis(tert-butylperoxy)-2,5-dimethylhexane, bis(tert-butyl peroxyisopropyl)benzene, and tert-butyl hydroperoxide), azo compounds (e.g., 2,2′-azobis(2-methyl-propanenitrile), 2,2′-azobis(2-methylbutanenitrile), and 1,1′-azobis(cyclohexanecarbonitrile)), and the like.

The term “free radical initiator” also includes photoinitiators. For example, for invention adhesive compositions that contain a photoinitiator, the curing process can be initiated by UV radiation. In one embodiment, the photoinitiator is present at a concentration of 0.1 wt % to 5 wt % based on the total weight of the organic compounds in the b-stageable adhesive composition (excluding any filler). In a one embodiment, the photoinitiator comprises 0.1 wt % to 3.0 wt %, based on the total weight of the organic compounds in the b-stageable adhesive composition. Photoinitiators include benzoin derivatives, benzilketals, α, α-dialkoxyacetophenones, α-hydroxyalkylphenones, α-aminoalkylphenones, acylphosphine oxides, titanocene compounds, combinations of benzophenones and amines or Michler's ketone, and the like.

In another embodiment of the invention, there are provided b-stageable die-attach pastes including 2 weight percent to about 98 weight percent (wt %) of at least one crosslinking monomer optionally, 10 wt % to about 90 wt % of at least one additional compound selected from the group consisting of acrylates, methacrylates, maleimides, vinyl ethers, vinyl esters, styrenic compounds, and allyl functional compounds, and the like, based on total weight of the composition; 0 to about 90 wt % of a conductive filler; 0.1 wt % to about 5 wt % of at least one curing initiator, based on total weight of the composition; and 0.1 wt % to about 4 wt %, of at least one coupling agent, based on total weight of the composition. In some embodiments, the additional compound includes, for example, epoxies (such as phenolics, novalacs (both phenolic and cresolic) and the like), imides, monomaleimides, bismaleimides, polymaleimides, cyanate esters, vinyl ethers, vinyl esters, vinyl acetates, esters, ureas, amides, olefins (such as ethylenes, propylenes, and the like) siloxanes, cyanoacrylates, styrenes, and the like, or combinations thereof.

Fillers contemplated for use in the practice of the present invention can be electrically conductive and/or thermally conductive, and/or fillers which act primarily to modify the rheology of the resulting composition. Examples of suitable electrically conductive fillers which can be employed in the practice of the present invention include silver, nickel, copper, aluminum, palladium, gold, graphite, metal-coated graphite (e.g., nickel-coated graphite, copper-coated graphite, and the like), and the like. Examples of suitable thermally conductive fillers which can be employed in the practice of the present invention include graphite, aluminum nitride, silicon carbide, boron nitride, diamond dust, alumina, and the like. Compounds which act primarily to modify rheology include polysiloxanes (such as polydimethyl siloxanes) silica, fumed silica, alumina, titania, and the like.

As used herein, the term “coupling agent” refers to chemical species that are capable of bonding to a mineral surface and which also contain polymerizably reactive functional group(s) so as to enable interaction with the adhesive composition. Coupling agents thus facilitate linkage of the die-attach paste to the substrate to which it is applied.

Exemplary coupling agents contemplated for use in the practice of the present invention include silicate esters, metal acrylate salts (e.g., aluminum methacrylate), titanates (e.g., titanium methacryloxyethylacetoacetate triisopropoxide), or compounds that contain a copolymerizable group and a chelating ligand (e.g., phosphine, mercaptan, acetoacetate, and the like). In some embodiments, the coupling agents contain both a co-polymerizable finction (e.g., vinyl moiety, acrylate moiety, methacrylate moiety, and the like), as well as a silicate ester function. The silicate ester portion of the coupling agent is capable of condensing with metal hydroxides present on the mineral surface of substrate, while the co-polymerizable function is capable of co-polymerizing with the other reactive components of invention die-attach paste. In certain embodiments coupling agents contemplated for use in the practice of the invention are oligomeric silicate coupling agents such as poly(methoxyvinylsiloxane).

In some embodiments, both photoinitiation and thermal initiation may be desirable. For example, curing of a photoinitiator-containing adhesive can be started by UV irradiation, and in a later processing step, curing can be completed by the application of heat to accomplish a free-radical cure. Both UV and thermal initiators may therefore be added to the adhesive composition.

In general, these b-stageable compositions will cure within a temperature range of 80-220° C., and curing will be effected within a length of time of less than 1 minute to 60 minutes. The b-stageable die-attach paste may be preapplied onto either a semiconductor die or onto a substrate. As will be understood by those skilled in the art, the time and temperature curing profile for each adhesive composition will vary, and different compositions can be designed to provide the curing profile that will be suited to the particular industrial manufacturing process.

In certain embodiments, the adhesive compositions may contain compounds that lend additional flexibility and toughness to the resultant cured adhesive. Such compounds may be any thermoset or thermoplastic material having a Tg of 50° C. or less, and typically will be a polymeric material characterized by free rotation about the chemical bonds, the presence of ether groups, and the absence of ring structures. Suitable such modifiers include polyacrylates, poly(butadiene), polyTHF (polymerized tetrahydrofuran, also known as poly(1,4-butanediol)), CTBN (carboxy-terminated butadiene-acrylonitrile) rubber, and polypropylene glycol. When present, toughening compounds may be in an amount up to about 15 percent by weight of the maleimide and other monofunctional vinyl compound.

Inhibitors for free-radial cure may also be added to the adhesive compositions and die-attach pastes described herein to extend the useful shelf life of compositions containing the polyester linked acrylates and methacrylates. Examples of these inhibitors include hindered phenols such as 2,6-di-tert-butyl-4-methylphenol; 2,6-di-tert-butyl-4-methoxyphenol; tert-butyl hydroquinone; tetrakis(methylene(3,5-di-tert-butyl-4-hydroxyhydrocinnamate))benzene; 2,2′-methylenebis(6-tert-butyl-p-cresol); and 1,3,5-trimethyl-2,4,6-tris(3′,5′-di-tert-butyl-4-hydroxybenzyl)benzene. Other useful hydrogen-donating antioxidants include derivatives of p-phenylenediamine and diphenylamine. It is also well know in the art that hydrogen-donating antioxidants may be synergistically combined with quinones, and metal deactivators to make a very efficient inhibitor package. Examples of suitable quinones include benzoquinone, 2-tert butyl-1,4-benzoquinone; 2-phenyl-1,4-benzoquinone; naphthoquinone, and 2,5-dichloro-1,4-benzoquinone. Examples of metal deactivators includeN,N′-bis(3,5-di-tert-butyl-4-hydroxyhydrocinnamoyl)hydrazine; oxalyl bis(benzylidenehydrazide); and N-phenyl-N′-(4-toluenesulfonyl)-p-phenylenediamine. Nitroxyl radical compounds such as TEMPO (2,2,6,6-tetramethyl-1-piperidnyloxy, free radical) are also effective as inhibitors at low concentrations. The total amount of antioxidant plus synergists typically falls in the range of 100 to 2000 ppm relative to the weight of total base resin. Other additives, such as adhesion promoters, in types and amounts known in the art, may also be added.

These compositions will perform within the commercially acceptable range for die attach adhesives. Commerically acceptable values for die shear for the adhesives on a 80×80 mil² silicon die are in the range of greater than or equal to 1 kg at room temperature, and greater than or equal to 0.5 kg at 240° C. Acceptable values for warpage for a 500×500 mil² die are in the range of less than or equal to 70 Nm at room temperature.

It is understood that using the compounds and methods of the present invention, it is possible to prepare adhesives having a wide range of cross-link density by the judicious choice and amount of crosslinking monomer. The greater proportion of polyfunctional compounds reacted, the greater the cross-link density. If thermoplastic properties are desired, the adhesive compositions can be prepared from (or at least contain a higher percentage of) mono-functional compounds to limit the cross-link density. A minor amount of poly-functional compounds can be added to provide some cross-linking and strength to the composition, provided the amount of poly-functional compounds is limited to an amount that does not diminish the desired thermoplastic properties. Within these parameters, the strength and elasticity of individual adhesives can be tailored to a particular end-use application.

“Cross-linking,” as used herein, refers to the attachment of two or more polymer chains by bridges of an element, a molecular group, or a compound. In general, crosslinking of the compounds of the invention takes place upon heating. As cross-linking density is increased, the properties of a material can be changed from thermoplastic to thermosetting.

While certain embodiments have been set forth to describe the invention, the invention is not limited thereto, and it will be apparent to those skilled in the art that various modifications can be applied within the spirit of the invention and scope of the claims.

What is claimed is:

1. A semiconductor die assembly comprising:
a) a substrate having wiring members extending from pads on the substrate for electrically connecting a die to the substrate,
b) a bottom die having a rear surface and a front surface, wherein the rear surface faces the substrate, and wherein the front surface of the bottom die has electrical pads for attaching a wiring member from the substrate, and wherein a first die-attach adhesive is disposed between the substrate and the bottom die,
c) at least one first top die having a rear surface and a front surface, wherein the first top die is positioned above the bottom die so that the rear surface of the first top die is facing the front surface of the bottom die, thereby creating a first bondline gap between the bottom die and the top die, wherein a portion of the wiring members extending from the electrical pads on the front surface of the bottom die are located within the first bondline gap, and
d) a second die-attach adhesive disposed between the bottom die and the top die, thereby filling the first bondline gap and creating a first bondline, and encapsulating the portion of the wiring members located within the first bondline.

2. The semiconductor die assembly of claim 1, further comprising a second top die having a rear surface and a front surface positioned above the first top die as in claim 1(c), wherein the second die-attach adhesive is disposed between the second top die and the first top die, thereby filling a second bondline gap and creating a second bondline, and encapsulating the portion of the wiring members located within the second bondline.

3. The semiconductor die assembly of claim 2, further comprising a third top die having a rear surface and a front surface positioned above the second top die as in claim 1(c), wherein the second die-attach adhesive is disposed between the third top die and the second top die, thereby filling a third bondline gap and creating a third bondline, and encapsulating the portion of the wiring members located within the third bondline.

4. The semiconductor die assembly of claim 1, wherein the bondline is 1 to about 10 mils.

5. The semiconductor die assembly of claim 1, wherein the bondline is 1 to about 5 mils.

6. The semiconductor die assembly of claim 1, wherein the bondline is about 3 mils.

7. The semiconductor die assembly of claim 1, wherein the assembly comprises at least 4 top die.
